(19) United States
(12) Patent Application Publication
(10) Pub. No.: US 2022/0059661 A1
(43) Pub. Date: Feb. 24, 2022

(54) OXIDE SEMICONDUCTOR MATERIAL, THIN FILM TRANSISTOR AND PREPARATION METHOD THEREFOR, AND DISPLAY PANEL

(71) Applicant: GUANGZHOU NEW VISION OPTO-ELECTRONIC TECHNOLOGY CO., LTD., Guangdong (CN)

(72) Inventors: Hua Xu, Guangdong (CN); Miao Xu, Guangdong (CN); Zikai Chen, Guangdong (CN); Min Li, Guangdong (CN); Jiawei Pang, Guangdong (CN); Junbiao Peng, Guangdong (CN); Lei Wang, Guangdong (CN); Jianhua Zou, Guangdong (CN); Hong Tao, Guangdong (CN)

(73) Assignee: GUANGZHOU NEW VISION OPTO-ELECTRONIC TECHNOLOGY CO., LTD., Guangdong (CN)

(21) Appl. No.: 17/312,885

(22) PCT Filed: Jul. 23, 2019
(86) PCT No.: PCT/CN2019/097280

§ 371 Date: Jun. 10, 2021

(30) Foreign Application Priority Data
Dec. 12, 2018 (CN) 201811519359.4

(51) Int. Cl. H01L 29/24; H01L 29/786; H01L 29/66

(52) U.S. Cl. CPC H01L 29/24; H01L 29/66969; H01L 29/7869

(57) ABSTRACT

Disclosed are an oxide semiconductor material, a thin-film transistor and a manufacturing method thereof, and a display panel. The oxide semiconductor material includes: a complex oxide (In₂O₃)ₐ(MO)_{b} composed of an oxide of indium In₂O₃ and an oxide of a fifth subgroup element MO, where a+b=1, and 0.10≤b≤0.50.

This application claims priority to Chinese patent application No. 201811519359.4 filed with the CNIPA on Dec. 12, 2018, the disclosure of which is incorporated herein by reference in its entirety.

### TECHNICAL FIELD

The present disclosure relates to the technical field of semiconductor materials and devices and, in particular, to an oxide semiconductor material, a thin-film transistor and a manufacturing method thereof, and a display panel.

### BACKGROUND

In recent years, the new flat panel display (FPD) industry has developed rapidly, and the demand for large-size, high-resolution flat panel displays is increasing. As the core technology of FPD industry, then thin-film transistor (TFT) backplane technology is undergoing profound changes. At present, materials of channel layers of semiconductors of thin-film transistors used for the flat panel display are mainly silicon materials including amorphous silicon, polycrystalline silicon, microcrystalline silicon and the like. However, the amorphous silicon thin-film transistor has defects of sensitivity to light, low mobility and poor stability, and cannot satisfy the requirements of driving an organic light-emitting diode (OLED) display; although the polycrystalline silicon thin-film transistor has relatively high mobility, the electrical uniformity of the polycrystalline silicon thin-film transistor is poor due to the influence of grain boundaries, and high temperature and high cost required for manufacturing the polycrystalline silicon thin-film transistor resulted from processes of ion implantation, activation and the like limit the application of the polycrystalline silicon thin-film transistor in the flat panel display; the microcrystalline silicon is difficult to manufacture since the difficult crystal grain control technology makes it not easy to achieve large-scale mass production. The metal oxide TFT not only has high mobility, can be manufactured at room temperature, and is transparent in visible light, but also has excellent large-area uniformity, so that the oxide TFT technology has attracted much attention since the birth of the oxide TFT technology.

However, at present, the use of oxide semiconductor materials in the manufacturing process of back-channel-etching-type thin-film transistors is obviously restricted, and it is difficult to achieve the manufacturing of high-performance devices.

### SUMMARY

The following is a summary of the subject matter described herein in detail. This summary is not intended to limit the scope of the claims.

In view of this, the present disclosure provides an oxide semiconductor material, a thin-film transistor and a manufacturing method thereof, and a display panel. The oxide semiconductor includes a complex metal oxide composed of an oxide of indium In₂O₃ and an oxide of a fifth subgroup element MO, so that the situation is avoided that the use of oxide semiconductor materials in the manufacturing process of back-channel-etching-type thin-film transistors is obviously restricted in the related art and it is difficult to achieve the manufacturing of high-performance devices.

In a first aspect, an embodiment of the present disclosure provides an oxide semiconductor material. The material includes: a complex oxide (In₂O₃)ₐ(MO)_{b} composed of an oxide of indium In₂O₃ and an oxide of a fifth subgroup element MO, where a+b=1, and 0.10≤b≤0.50.

In a second aspect, an embodiment of the present disclosure provides a thin-film transistor. The thin-film transistor includes: a substrate; a gate layer formed on the substrate; an insulating layer formed on the gate layer; an active layer formed on the insulating layer; and a patterned source electrode and a patterned drain electrode which are formed on the active layer and are respectively electrically connected to the active layer. The active layer includes the oxide semiconductor material of the first aspect.

In a third aspect, an embodiment of the present disclosure provides a thin-film transistor. The thin-film transistor includes: a substrate; a gate layer formed on the substrate; an insulating layer formed on the gate layer; an active layer formed on the insulating layer; and a patterned source electrode and a patterned drain electrode which are formed on the active layer and are respectively electrically connected to the active layer. The active layer includes a channel layer and a channel protective layer, and a material of the channel protective layer includes the oxide semiconductor material of the first aspect.

In a fourth aspect, an embodiment of the present disclosure provides a manufacturing method of a thin-film transistor based on the thin-film transistor of any one of the second aspect or the third aspect. The method includes the steps described below. A substrate is provided; a gate layer, an insulating layer, and an active layer are sequentially formed on the substrate; and a source electrode layer and a drain electrode layer are formed on the active layer, and a patterned source electrode and a patterned drain electrode are formed by performing an etching process respectively on the source electrode layer and the drain electrode layer. The etching process includes wet etching and dry etching. The active layer includes the oxide semiconductor material of the first aspect of the claims.

In a fifth aspect, an embodiment of the present disclosure provides a display panel. The display panel includes the thin-film transistor of any one of the second aspect or the third aspect.

Other aspects can be understood after the drawings and the detailed description are read and understood.

### BRIEF DESCRIPTION OF DRAWINGS

FIG. 1 is a structural view of a thin-film transistor device according to an embodiment of the present disclosure;

FIG. 2 is a structural view of a thin-film transistor device according to an embodiment of the present disclosure; and

FIG. 3 is a schematic flowchart illustrating a manufacturing method of a thin-film transistor according to an embodiment of the present disclosure.

### DETAILED DESCRIPTION

The present disclosure is further described in detail hereinafter in combination with drawings and embodiments. It is to be understood that the example embodiments described below are merely intended to illustrate but not to limit the present disclosure. It should be noted that to facilitate description, only part, not all, of structures related to the present disclosure are illustrated in the drawings.

An embodiment of the present disclosure provides an oxide semiconductor material. The material includes: a complex oxide (In₂O₃)ₐ(MO)_{b} composed of an oxide of indium In₂O₃ and an oxide of a fifth subgroup element MO, where a+b=1, and 0.10≤b≤0.50.

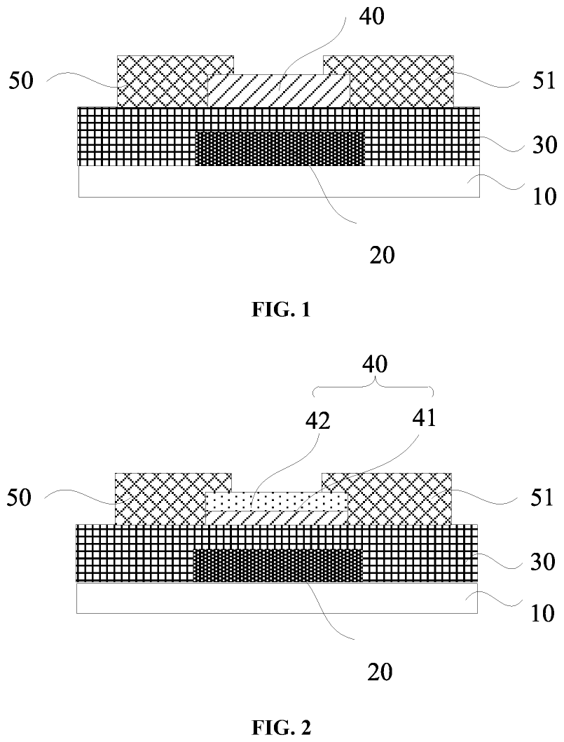

In the embodiment, the oxide of indium In₂O₃ is an n-type semiconductor having a stable cubic bixbyite structure. Since the intrinsic carrier concentration of the oxide of indium In₂O₃ can reach 10²⁰ cm⁻³ and the optical band gap of the oxide of indium In₂O₃ is between 2.67 eV to 3.75 eV, the oxide of indium In₂O₃ has high transparency to visible light and is mainly applied to the field of transparent conductive thin films. In a case where an oxide semiconductor material is used for a thin-film transistor device, referring to FIG. 1, the oxide semiconductor material is often used as an active layer 40 of the thin-film transistor device. In addition, the thin-film transistor device further includes a substrate 10; a gate layer 20 formed on the substrate 10; an insulating layer 30 formed on the gate layer 20; an active layer 40 formed on the insulating layer 30; and a patterned source electrode 50 and a patterned drain electrode 51 which are formed on the active layer 40. The source electrode 50 and the drain electrode 51 are respectively electrically connected to the active layer 40.

It should be noted that the active layer 40 may individually include a channel layer or may include two layers, and the two layers are constructed by a channel layer and a channel protective layer above the channel layer.

For the thin-film transistor device, too high carrier concentration of In₂O₃ makes it difficult for In₂O₃ to be used as the active layer of the device. In addition, binary indium oxide In₂O₃ is extremely easy to crystallize, and polycrystalline In₂O₃ thin films are difficult to pattern, and patterning is difficult to achieve in the manufacturing of the thin-film transistor device.

On the basis of the above solution, the oxide of the fifth subgroup element MO includes at least one of vanadium oxide, niobium oxide, or tantalum oxide.

In the embodiment of the present disclosure, the oxide of the fifth subgroup element MO is doped into the binary indium oxide In₂O₃. The oxide of the fifth subgroup element MO is an octahedral or bipyramidal structure, and the radius of ions of MO is about 60 pm, where the radius of vanadium ions is about 54 pm, the radius of niobium ions is about 64 pm, and the radius of tantalum ions is about 64 pm, which are all smaller than the radius of indium ions, and the radius of indium ions is about 80 pm. On the one hand, oxides of the fifth subgroup element with a relatively small ionic radius easily enter the crystal structure of In₂O₃ and form efficient doping, which microscopically causes the lattice distortion of indium-oxygen octahedron InO₆ and inhibits the crystal growth of In₂O₃. On the other hand, oxides of the fifth subgroup element are mostly octahedral or bipyramidal structures and can be better matched with the cubic bixbyite structure. Thus, the thin film formed by the complex oxide semiconductor is easy to be a microcrystalline structure, instead of a thin film of an amorphous structure being formed. Therefore, the damage caused by an etching solution with relatively strong corrosivity and caused by plasma bombardment is avoided. Secondly, compared with the electronegativity of indium (about 1.78), the fifth subgroup element has relatively low electronegativity (the electronegativity of vanadium is about 1.63, the electronegativity of niobium is about 1.60, and the electronegativity of tantalum is about 1.50), so that the fifth subgroup element can form stronger ionic bonds (M-O) with oxygen O and thus has stronger binding capability to oxygen. Therefore, the formation of oxygen vacancies is inhibited, and the intrinsic carrier concentration of the thin film formed by the complex oxide semiconductor is reduced to a certain extent. Further, the scattering of electron transport in oxides with high indium content and low indium content is very serious, which makes the carrier mobility of the thin film formed by the complex oxide semiconductor relatively low. The doping of a certain amount of the fifth subgroup oxide makes the bond angle (M-O-M) of ions of the metal M in the composition change to a certain extent, increases the edge-shared and surface-shared components in the polyhedron, obviously improves the smoothness of electron transport, and thus ensures relatively high carrier mobility. Finally, after the fifth subgroup oxide is doped into indium oxide, a certain amount of band gap state is formed adjacent to Fermi level, which can effectively compensate for the impact on the thin film formed by the complex oxide semiconductor in plasma and improve the process window of the thin film formed by the complex oxide semiconductor in device manufacturing. Moreover, the generation of the band gap state can effectively suppress the photo-generated current effect and improve the light stability of the device.

In the above oxide semiconductor material, in a case where the molecular ratio (b) of the fifth subgroup oxide MO is less than 0.1, the formed thin film may be a polycrystalline structure. As a result, on the one hand, it is difficult to etch and pattern the thin film itself; on the other hand, angle-shared components in the polyhedron in the thin film are relatively large, and the probability of scattering of carrier transport increases, leading to low mobility and poor stability of the manufactured device. In a case where b is greater than 0.5, the formation of oxygen vacancies is obviously inhibited, and the intrinsic carrier concentration in the thin film is relatively low, resulting in low mobility and relatively large subthreshold swing of the manufactured device.

Compared with the related art, the oxide semiconductor material of the present disclosure is the oxide semiconductor material (In₂O₃)ₐ(MO)_{b} composed and formed by doping the fifth subgroup oxide MO in indium oxide In₂O₃, so that the oxide semiconductor material can effectively resist etching by a wet etching solution and plasma bombardment. The thin-film transistor adopting the oxide semiconductor material of the embodiment of the present disclosure as the material of the channel layer can be used to achieve the manufacturing of the back-channel-etching-type device. The manufactured device has good switching characteristics and excellent stability. The process window of manufacturing the thin-film transistor adopting the oxide semiconductor material of the embodiment of the present disclosure as the channel layer or the channel protective layer is relatively large, so that the manufacturing of high-precision (relatively-short-channel-length) devices can be achieved.

The embodiment of the present disclosure provides an oxide semiconductor material. The oxide semiconductor includes a complex metal oxide composed of an oxide of indium In₂O₃ and an oxide of a fifth subgroup element MO, so that the situation is avoided that the use of oxide semiconductor materials in the manufacturing process of back-channel-etching-type thin-film transistors is obviously restricted in the related art and it is difficult to achieve the manufacturing of high-performance devices.

On the basis of the above solution, 0.15≤b≤0.30. In the above oxide semiconductor material, in a case where the molecular ratio (b) of the fifth subgroup oxide MO is greater than or equal to 0.15 and is less than or equal to 0.30, the crystal type is a microcrystalline type, and the manufactured device has high carrier mobility and good stability.

On the basis of the above solution, the crystal type of the complex oxide (In₂O₃)ₐ(MO)_{b} is the microcrystalline type. The thin film formed by the oxide semiconductor of the amorphous structure is susceptible to the damage caused by an etching solution with relatively strong corrosivity and caused by plasma bombardment. In a case where the thin film formed by the oxide semiconductor of a polycrystalline structure is used as the channel layer in the thin-film transistor, the manufactured device is in a turn-on state and loses switching characteristics.

On the basis of the above solution, the oxide semiconductor material further includes a complex oxide composed of an oxide of an element X XO, the oxide of indium In₂O₃, the oxide of the fifth subgroup element MO, and the oxide of X XO, and the chemical formula of the complex oxide is (In₂O₃)_{c}(MO)_{d}(XO)ₑ. The oxide of the element X XO includes an oxide formed by at least one of a first main group element, a second main group element, a third main group element, a fourth main group element, a fifth main group element, a sixth main group element, or lanthanide, and c+d+e=1. In the complex oxide (In₂O₃)_{c}(MO)_{d}(XO)ₑ, the ratio of the number of atoms of the element X to the sum of the number of atoms of the element In, the number of atoms of a fifth subgroup element M, and the number of atoms of the element X is greater than or equal to 0.01 and is less than or equal to 0.15. In the embodiment, the ratio of the number of atoms of the fifth subgroup element to the sum of the number of atoms of the element In and the number of atoms of the fifth subgroup element M is about 0.15. The oxide thin-film transistor manufactured by adopting the above oxide semiconductor material has a large patterning window for the source electrode and the drain electrode, so that the oxide thin-film transistor can resist the damage to the channel layer caused by a wet etching solution and plasma bombardment, the manufacturing of the back-channel-etching-type device can be achieved, and the manufactured thin-film transistor has excellent switching performance and good stability.

On the basis of the above embodiment, an embodiment of the present disclosure provides a thin-film transistor. FIG. 1 is taken as an example, and the thin-film transistor includes: a substrate 10; a gate layer 20 formed on the substrate 10; an insulating layer 30 formed on the gate layer 20; an active layer 40 formed on the insulating layer 30; and a patterned source electrode 50 and a patterned drain electrode 51 which are formed on the active layer 40. The source electrode 50 and the drain electrode 51 are respectively electrically connected to the active layer 40. The active layer 40 includes the oxide semiconductor material of the above embodiment.

In the embodiment of the present disclosure, the active layer of the thin-film transistor includes the oxide semiconductor material in the above embodiment. The microcrystalline oxide semiconductor material (In₂O₃)ₐ(MO)_{b} is composed and formed by doping the fifth subgroup oxide MO in indium oxide In₂O₃, so that the oxide semiconductor material can effectively resist etching by a solution of wet etching and plasma bombardment. The thin-film transistor adopting the oxide semiconductor material of the embodiment of the present disclosure as the material of the channel layer can be used to achieve the manufacturing of the back-channel-etching-type device. The manufactured device has good switching characteristics and excellent stability. The process window of manufacturing the thin-film transistor adopting the oxide semiconductor material of the embodiment of the present disclosure as the channel layer or the channel protective layer is relatively large, so that the manufacturing of high-precision (relatively-short-channel-length) devices can be achieved.

On the basis of the above solution, the embodiment of the present disclosure further provides a thin-film transistor. FIG. 2 is taken as an example, and the thin-film transistor includes: a substrate 10; a gate layer 20 formed on the substrate 10; an insulating layer 30 formed on the gate layer 20; an active layer 40 formed on the insulating layer 30; and a patterned source electrode 50 and a patterned drain electrode 51 which are formed on the active layer 40. The source electrode 50 and the drain electrode 51 are respectively electrically connected to the active layer 40. The active layer 40 includes a channel layer 41 and a channel protective layer 42, and the channel protective layer 42 includes the oxide semiconductor material of the above embodiment. In an embodiment, the channel layer 41 may also be made of the oxide semiconductor material of the above embodiment.

On the basis of the above solution, a passivation layer may further be included above the source electrode 50 and the drain electrode 51.

It should be particularly pointed out that the material of the oxide semiconductor and the thin-film transistor thereof of the present disclosure are not limited by the device structure, and as long as the semiconductor layer thereof contains the oxide semiconductor material of the present disclosure, other configurations are not particularly limited and may be a device structure well known in the art. The thin-film transistor provided by the present disclosure is a special application of the oxide semiconductor material of the present disclosure in the art.

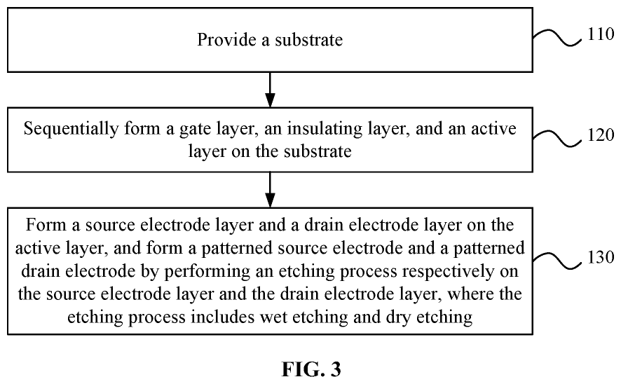

On the basis of the above embodiment, an embodiment of the present disclosure provides a manufacturing method of a thin-film transistor. Based on the thin-film transistor shown in FIG. 1, referring to FIG. 3, the manufacturing method includes steps 110 to 130.

In step 110, a substrate is provided.

In step 120, a gate layer, an insulating layer, and an active layer are sequentially formed on the substrate.

In step 130, a source electrode layer and a drain electrode layer are formed on the active layer, and a patterned source electrode and a patterned drain electrode are formed by performing an etching process respectively on the source electrode layer and the drain electrode layer. The etching process includes wet etching and dry etching. The active layer includes the oxide semiconductor material of the above embodiment.

On the basis of the above solution, the oxide semiconductor material is manufactured by any one of a physical vapor deposition process, a chemical vapor deposition process, an atomic layer deposition process, a laser deposition process, or a solution method process.

Hereinafter, each functional layer of the thin-film transistor of the embodiment of the present disclosure is further described.

The substrate in the present disclosure is not particularly limited, and substrates known in the art may be used. For example, hard alkali glass, alkali-free glass, quartz glass, silicon substrate and the like may be used. Flexible polyimide (PI), polyethylene naphthalate (PEN), polyethylene glycol terephthalate (PET), polyethylene (PE), polypropylene (PP), polystyrene (PS), poly ether sulfones (PES), or a metal sheet may be used.

The material of the gate in the present disclosure is not particularly limited, and may be freely selected from materials known in the art. For example, the material of the gate may be a transparent conductive oxide (indium tin oxide (ITO), aluminum zinc oxide (AZO), gallium zinc oxide (GZO), indium zinc oxide (IZO), indium tin zinc oxide (ITZO), fluorine tin oxide (FTO), etc.), a metal (molybdenum (Mo), aluminum (Al), copper (Cu), silver (Ag), titanium (Ti), gold (Au), tantalum (Ta), chromium (Cr), nickel (Ni), etc.) and an alloy thereof, and may be a complex conductive thin film formed by stacking metals and oxides (ITO/Ag/ITO, IZO/Ag/IZO, etc.) and formed by stacking metals and metals (Mo/Al/Mo, Ti/Al/Ti, etc.).

The manufacturing method of the gate thin film may be a sputtering method, a thermal evaporation method, and other deposition methods. For example, the sputtering deposition method is selected since the thin film manufactured by this method has good adhesion to the substrate, excellent uniformity, and can be manufactured in a large area.

Here, the specific structure of the gate electrode to be used is determined according to the technical parameters to be achieved. For example, a transparent electrode needs to be used in transparent display, a single layer of ITO may be taken as the gate electrode or ITO/Ag/ITO may be taken as the gate electrode. In addition, if high-temperature processes are required for applications in special fields, the gate electrode may be a metal alloy thin film that can resist high temperatures.

The material of the gate insulating layer of the present disclosure is not particularly limited, and may be freely selected from materials known in the art. For example, silicon oxide, silicon nitride, aluminum oxide, tantalum oxide, hafnium oxide, yttrium oxide, and polymer organic film layers may be selected.

It should be pointed out that the components of these insulating thin films may be inconsistent with theoretical stoichiometric ratios. In addition, the gate insulating layer may be formed by stacking multiple insulating films, which can form better insulating characteristics on the one hand, and can improve the interface characteristics between the channel layer and the gate insulating layer on the other hand. Moreover, the gate insulating layer may be manufactured in multiple manners, such as physical vapor deposition, chemical vapor deposition, atomic layer deposition, laser deposition, anodic oxidation, or a solution method.

The channel layer or the channel protective layer in the disclosure is an oxide semiconductor material, which is a microcrystalline oxide semiconductor material (In₂O₃)ₐ(MO)_{b} composed of indium oxide In₂O₃ and a fifth subgroup oxide MO; and a+b=1, and 0.10≤b≤0.50.

In an embodiment, the molecular ratio of the fifth subgroup oxide MO in the oxide semiconductor material is greater than or equal to 0.15 and is less than or equal to 0.30, that is, 0.15≤b≤0.30.

In an embodiment, the oxide semiconductor material further includes a complex oxide composed of an oxide of an element X XO, the oxide of indium In₂O₃, the oxide of the fifth subgroup element MO, and the oxide of X XO, and the chemical formula of the complex oxide is (In₂O₃)_{c}(MO)_{d}(XO)ₑ. The oxide of the element X XO includes an oxide formed by at least one of a first main group element, a second main group element, a third main group element, a fourth main group element, a fifth main group element, a sixth main group element, or lanthanide, and c+d+e=1. In the complex oxide (In₂O₃)_{c}(MO)_{d}(XO)ₑ, the ratio of the number of atoms of the element X to the sum of the number of atoms of the element In, the number of atoms of a fifth subgroup element M, and the number of atoms of the element X is greater than or equal to 0.01 and is less than or equal to 0.15.

It should be noted that in a case where the content of the fifth subgroup element M in the channel layer of the device is too low, the film is a polycrystalline structure, and the manufactured device is in a turn-on state and loses switching characteristics. In a case where the content of the fifth subgroup element M in the channel is too high, the thin film is an amorphous structure. Therefore, during the etching process of the source electrode and the drain electrode, the channel layer is completely etched, and the manufacturing of the back-channel-etching-type device cannot be achieved.

The etching solution used in wet etching includes: a mixture of phosphoric acid, nitric acid, and glacial acetic acid or a mixture based on hydrogen peroxide. The etching rate of the oxide semiconductor material in the above etching solution is less than 1 nm/min. For the wet etching, exemplarily, a plasma etching process may be selected, and etching gases include a chlorine-based or fluorine-based gas.

Exemplarily, referring to FIG. 2, in a case where the active layer 40 includes a channel protective layer, the channel protective layer 42 adopts the complex oxide (In₂O₃)ₐ(MO)_{b} composed of the oxide of indium In₂O₃ and the oxide of the fifth subgroup element MO, where a+b=1, and 0.10≤b≤0.50, or adopts the complex oxide (In₂O₃)_{c}(MO)_{d}(XO)ₑ composed of the oxide of the element X XO, the oxide of indium In₂O₃, the oxide of the fifth subgroup element MO, and the oxide of X XO, and the oxide of the element X XO includes an oxide formed by at least one of a first main group element, a second main group element, a third main group element, a fourth main group element, a fifth main group element, a sixth main group element, or lanthanide, where c+d+e=1. In the complex oxide (In₂O₃)_{c}(MO)_{d}(XO)ₑ, the ratio of the number of atoms of the element X to the sum of the number of atoms of the element In, the number of atoms of the fifth subgroup element M, and the number of atoms of the element X is greater than or equal to 0.01 and is less than or equal to 0.15.

The carrier concentration of the thin film of the oxide semiconductor material is between 1×10¹⁶ cm⁻³ and 5×10¹⁹ cm⁻³.

During a vacuum sputtering process of the oxide semiconductor material, single target sputtering or multi-target co-sputtering may be selected. For example, the single target sputtering is selected.

The single target sputtering can provide a thin film with better repeatability and stability, and the microstructure of the thin film is easier to control; while during co-sputtering of the thin film, sputtered particles will be affected by more factors during the recombination process.

During the vacuum sputtering deposition process, the power supply may be selected from radio frequency (RF) sputtering, direct current (DC) sputtering or alternating current (Alternating Current, AC) sputtering. For example, the AC sputtering commonly used in the industry is selected.

During the sputtering deposition process, the sputtering pressure is 0.1 Pa to 10 Pa. For example, the sputtering pressure is 0.2 Pa to 0.5 Pa.

If the sputtering pressure is too low, stable glow sputtering cannot be maintained; if the sputtering pressure is too high, the scattering of the sputtered particles during deposition on the substrate increases significantly, the energy loss increases, and the kinetic energy of the sputtered particles decreases after the sputtered particles reach the substrate. Therefore, The defects of the thin film increase, which seriously affects the performance of the device.

During the sputtering deposition process, the oxygen partial pressure is 0 Pa to 1 Pa. In an embodiment, the oxygen partial pressure is 0.001 Pa to 0.5 Pa. In an embodiment, the oxygen partial pressure is 0.01 Pa to 0.1 Pa.

Generally, in the process of manufacturing oxide semiconductors by sputtering, the oxygen partial pressure has a direct effect on the carrier concentration of the thin film, and some oxygen vacancy-related defects are introduced. Too low oxygen content may cause serious oxygen mismatch in the thin film and increase the carrier concentration; while too high oxygen vacancies causes more weak bonding bonds and reduce the reliability of the device.

During the sputtering deposition process, a substrate temperature is, for example, 200° C. to 300° C.

During the deposition of the thin film of the channel layer, a certain substrate temperature can help effectively improve the bonding manner of the sputtered particles after the sputtered particles reach the substrate, reduce the existence probability of weak bonding bonds, and improve the stability of the device. Of course, the same effect can also be achieved through subsequent annealing treatment and other processes.

The thickness of the channel layer is 2 nm to 100 nm. In an embodiment, the thickness of the channel layer is 5 nm to 50 nm. In an embodiment, the thickness of the channel layer is 10 nm to 40 nm.

The thickness of the channel protective layer is 2 nm to 100 nm. In an embodiment, the thickness of the channel protective layer is 5 nm to 30 nm. In an embodiment, the thickness of the channel protective layer is 5 nm to 20 nm.

The material of the source electrode and the drain electrode in the present disclosure is not particularly limited, and may be freely selected from materials known in the art without affecting the achieving of various required structural devices. For example, the material of the source electrode and the drain electrode may be a transparent conductive oxide (ITO, AZO, GZO, IZO, ITZO, FTO, etc.), a metal (Mo, Al, Cu, Ag, Ti, Au, Ta, Cr, Ni, etc.) and an alloy thereof, and may be a complex conductive thin film formed by stacking metals and oxides (ITO/Ag/ITO, IZO/Ag/IZO, etc.) and formed by stacking metals and metals (Mo/Al/Mo, Ti/Al/Ti, etc.).

The manufacturing method of the thin film of the source electrode and the drain electrode may be a sputtering method, a thermal evaporation method, and other deposition methods. For example, the sputtering deposition method is selected since the thin film manufactured by this method has good adhesion to the substrate, excellent uniformity, and can be manufactured in a large area.

Here, it should be particularly noted that in the manufacturing of the device with a back-channel-etching type structure, an appropriate etching selectivity is required for the source electrode and the drain electrode and the channel layer, otherwise the manufacturing of the device cannot be achieved. The etching solution for wet etching in the embodiment of the present disclosure is an etching solution based on conventional metals in the industry (such as phosphoric acid, nitric acid, acetic acid and other etching solutions, and hydrogen peroxide water-based etching solutions, etc.). The main reason is that the oxide semiconductor material of the present disclosure can effectively resist the etching of wet etching solutions (such as aqueous solutions of phosphoric acid, nitric acid, and acetic acid), and has a high etching selectivity with metals (such as molybdenum, molybdenum alloy, molybdenum/aluminum/molybdenum, etc.). The oxide semiconductor layer is basically not affected by the etching solution, and the manufactured device has excellent performance and good stability. In addition, dry etching in the embodiment of present disclosure is based on conventional etching gases in the industry (such as a chlorine-based gas, a fluorine-based gas, etc.). These etching gases have little effect on the oxide semiconductor layer of the present disclosure, so that the manufactured device has excellent performance and good stability.

The material of the passivation layer in the present disclosure is not particularly limited, and may be freely selected from materials known in the art. For example, silicon oxide, silicon nitride, aluminum oxide, tantalum oxide, hafnium oxide, yttrium oxide, and polymer organic film layers may be selected.

It should be pointed out that the components of these insulating thin films may be inconsistent with theoretical stoichiometric ratios. In addition, the gate insulating layer may be formed by stacking multiple insulating films, which can form better insulating characteristics on the one hand, and can improve the interface characteristics between the channel layer and the passivation layer on the other hand. Moreover, the passivation layer may be manufactured in multiple manners, such as physical vapor deposition, chemical vapor deposition, atomic layer deposition, laser deposition, or a solution method.

Hereinafter, the processing in the manufacturing process of the thin-film transistor of the embodiment of the present disclosure is further described.

Comparatively, due to the participation of high-energy plasma in the sputtering of manufacturing the thin film, the deposition rate of the thin film is generally relatively fast. Thus, the thin film does not have enough time to perform a relaxation process during the deposition process, which causes a certain degree of dislocation and cause stress to remain in the thin film. This requires later heating and annealing treatment to continue to achieve the required relatively-steady state and improve the performance of the thin film.

In the implementation of the present disclosure, the annealing treatment is mostly performed after the deposition of the channel layer and after the deposition of the passivation layer. On the one hand, the annealing treatment performed after the deposition of the channel layer can effectively improve in-situ defects in the channel layer and improve the capability of the channel layer to resist a possible damage in subsequent processes. On the other hand, in the subsequent deposition process of the passivation layer, due to the participation of plasma and the modification effect of active groups, an activation process may be required to further eliminate an interface state and some donor doping effects.

In addition, in the implementation of the present disclosure, the treatment method may not only be heating treatment, but also may include plasma treatment on the interface (such as a gate insulating layer/semiconductor interface, a channel layer/passivation layer interface, etc.).

Through the above treatment processes, the performance and the stability of the device can be effectively improved.

On the basis of the above solution, an embodiment of the present disclosure provides a display panel. The display panel includes the thin-film transistor involved in the above embodiments. The thin-film transistor is used to drive a display unit in the display panel.

What is claimed is:

1. An oxide semiconductor material, comprising:
a complex oxide (In₂O₃)ₐ(MO)_{b} composed of an oxide of indium In₂O₃ and an oxide of a fifth subgroup element MO, wherein a+b=1, and 0.10≤b≤0.50.

2. The oxide semiconductor material of claim 1,
wherein the oxide of the fifth subgroup element MO comprises at least one of vanadium oxide, niobium oxide, or tantalum oxide.

3. The oxide semiconductor material of claim 1, wherein 0.15≤b≤0.30.

4. The oxide semiconductor material of claim 1, wherein
a crystal type of the complex oxide (In₂O₃)ₐ(MO)_{b} is a microcrystalline type.

5. The oxide semiconductor material of claim 1, further comprising an oxide of an element X XO;
wherein a chemical formula of a complex oxide composed of the oxide of indium In₂O₃, the oxide of the fifth subgroup element MO and the oxide of X XO is (In₂O₃)_{c}(MO)_{d}(XO)ₑ, and the oxide of the element X XO comprises an oxide formed by at least one of a first main group element, a second main group element, a third main group element, a fourth main group element, a fifth main group element, a sixth main group element, or a lanthanide element;
wherein c+d+e=1, and in the complex oxide (In₂O₃)_{c}(MO)_{d}(XO)ₑ, a ratio of a number of atoms of the element X to a sum of a number of atoms of the element indium In, a number of atoms of a fifth subgroup element M, and a number of atoms of the element X is greater than or equal to 0.01 and is less than or equal to 0.15.

6. A thin-film transistor, comprising:
a substrate;
a gate layer formed on the substrate;
an insulating layer formed on the gate layer;
an active layer formed on the insulating layer; and
a source electrode and a drain electrode both patterned and formed on the active layer, wherein the source electrode and the drain electrode are respectively electrically connected to the active layer;
wherein the active layer comprises an oxide semiconductor material,
wherein the oxide semiconductor material comprises:
a complex oxide (In₂O₃)ₐ(MO)_{b} composed of an oxide of indium In₂O₃ and an oxide of a fifth subgroup element MO, wherein a+b=1, and 0.10≤b≤0.50.

7. A thin-film transistor, comprising:
a substrate;
a gate layer formed on the substrate;
an insulating layer formed on the gate layer;
an active layer formed on the insulating layer; and
a source electrode and a drain electrode both patterned and formed on the active layer, wherein the source electrode and the drain electrode are respectively electrically connected to the active layer;
wherein the active layer comprises a channel layer and a channel protective layer, and a material of the channel protective layer comprises an oxide semiconductor material,
wherein the oxide semiconductor material comprises:
a complex oxide (In₂O₃)ₐ(MO)_{b} composed of an oxide of indium In₂O₃ and an oxide of a fifth subgroup element MO, wherein a+b=1, and 0.10≤b≤0.50.

8. A preparing method of a thin-film transistor based on the thin-film transistor of claim 6, comprising:
providing a substrate;
sequentially forming a gate layer, an insulating layer, and an active layer on the substrate; and
forming a source electrode layer and a drain electrode layer on the active layer, and forming a patterned source electrode and a patterned drain electrode by performing an etching process respectively on the source electrode layer and the drain electrode layer, wherein the etching process comprises wet etching and dry etching;
wherein the active layer comprises the oxide semiconductor material of claim 1.

9. The preparing method of a thin-film transistor of claim 8, wherein
the oxide semiconductor material is prepared by any one of a physical vapor deposition process, a chemical vapor deposition process, an atomic layer deposition process, a laser deposition process, or a solution deposition process.

10. A display panel, comprising the thin-film transistor of claim 6.

11. A preparing method of a thin-film transistor based on the thin-film transistor of claim 7, comprising:
providing a substrate;
sequentially forming a gate layer, an insulating layer, and an active layer on the substrate; and
forming a source electrode layer and a drain electrode layer on the active layer, and forming a patterned source electrode and a patterned drain electrode by performing an etching process respectively on the source electrode layer and the drain electrode layer, wherein the etching process comprises wet etching and dry etching;
wherein the active layer comprises the oxide semiconductor material of claim 1.

12. The preparing method of a thin-film transistor of claim 11, wherein
the oxide semiconductor material is prepared by any one of a physical vapor deposition process, a chemical vapor deposition process, an atomic layer deposition process, a laser deposition process, or a solution deposition process.

13. A display panel, comprising the thin-film transistor of claim 7.
